(19) United States
(12) Patent Application Publication
(10) Pub. No.: US 2013/0286752 A1
(43) Pub. Date: Oct. 31, 2013

(54) SEMICONDUCTOR MEMORY

(71) Applicant: KABUSHIKI KAISHA TOSHIBA, Tokyo (JP)

(72) Inventors: Yoshihisa Michioka, Kanagawa-ken (JP); Mitsuhiro Abe, Kanagawa-ken (JP); Toshifumi Watanabe, Kanagawa-ken (JP); Shintaro Hayashi, Kanagawa-ken (JP); Hitoshi Ohta, Kanagawa-ken (JP)

(21) Appl. No.: 13/840,024

(22) Filed: Mar. 15, 2013

(30) Foreign Application Priority Data
Apr. 27, 2012 (JP) 2012-104008

(51) Int. Cl. G11C 7/10

(52) U.S. Cl. CPC G11C 7/1006
USPC 365/189.05

(57) ABSTRACT

A semiconductor memory according to one embodiment includes: a memory cell array including a plurality of memory cells storing data, a first buffer circuit for inputting/outputting data to and from the first memory cell array, a data transfer circuit connected with the first buffer circuit via the first data bus and configured to control data transfer, and a control circuit configured to control a first mode and a second mode. The data transfer circuit performs control such that a bus width of the first data bus differs between the first mode and the second mode.

### CROSS-REFERENCE TO RELATED APPLICATION

This application is based upon and claims the benefit of priority from the prior Japanese Patent Application No. 2012-104008, filed Apr. 27, 2012, the entire contents of which are incorporated herein by reference.

### FIELD

Embodiments of the present invention relate to a semiconductor memory, and particularly to a semiconductor memory having multiple operation modes in one chip.

### BACKGROUND

Recently, flash memories have been used for various electronic devices as main storage devices together with HDDs, CD/DVDs, and the like.

For example, what are required for the flash memories are speed-up of data input/output, improvement in reliability of an operation, and manufacturing cost reduction.

### DESCRIPTION OF THE DRAWINGS

FIG. 1 is a block diagram showing one example of a circuit configuration of a semiconductor memory according to an embodiment;

FIG. 2 is a drawing showing one example of a layout on a chip of the semiconductor memory according to the embodiment;

FIG. 3 is a schematic diagram showing one example of an internal configuration of a memory cell array;

FIG. 4 is a schematic diagram showing one example of configurations of a page buffer and a data transfer circuit;

FIG. 5 is a schematic diagram showing one example of the internal configuration of the page buffer;

FIG. 6 is a schematic diagram showing one example of the internal configuration of the page buffer;

FIG. 7 is a drawing for illustrating one example of an operation of the semiconductor memory according to the embodiment;

FIG. 8 is a timing chart showing one example of the operation of the semiconductor memory according to the embodiment;

FIG. 9 is a timing chart showing one example of the operation of the semiconductor memory according to the embodiment;

FIG. 10 is a timing chart showing one example of the operation of the semiconductor memory according to the embodiment;

FIG. 11 is a timing chart showing one example of the operation of the semiconductor memory according to the embodiment;

FIG. 12 is a drawing for illustrating one example of an application of the semiconductor memory according to the embodiment; and

FIG. 13 is a drawing for illustrating one example of the application of the semiconductor memory according to the embodiment.

### DETAILED DESCRIPTION

A semiconductor memory according to one embodiment includes: a first memory cell array including a plurality of memory cells configured to store data, a first buffer circuit for inputting/outputting data to and from the first memory cell array, a data transfer circuit connected with the first buffer circuit via a first data bus and configured to control data transfer based on a first mode for transferring data with a first bit width and a second mode for transferring data with a second bit width different from the first bit width, and an ECC circuit connected with the first data bus via the data transfer circuit and configured to perform ECC processing on data with the second bit width. The first buffer circuit includes a plurality of pipe circuits each configured to input and output data with the first bit width, and the data transfer circuit includes a first data storage unit connected with the first data bus and having a plurality of first latch circuits configured to respectively stored a plurality of data with the first bit width transferred from the pipe circuits, and a selection circuit configured to connect one of the plurality of first latch circuits with a second data bus based on a selection signal, and a second data storage unit connected between the first data bus and the ECC circuit and configured to store the data with the second bit width.

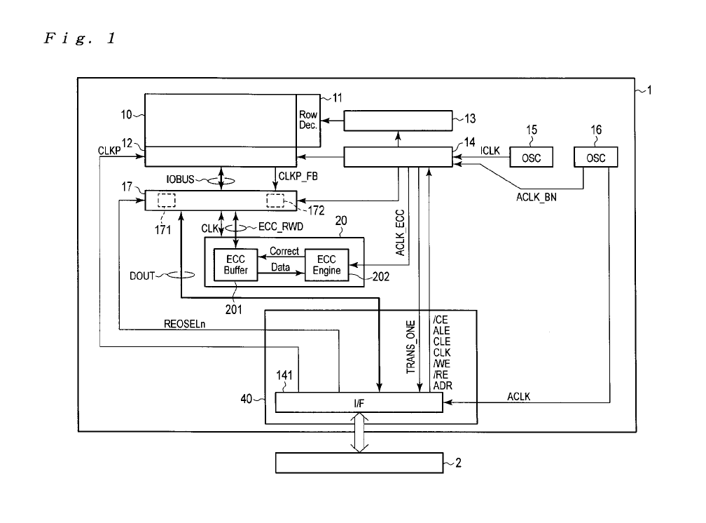

Hereinafter, a semiconductor memory according to an embodiment will be described in detail with reference to FIGS. 1 to 13. In the following description of the drawings, same reference numerals are given to denote elements having a same function and configuration, and the duplicated description is given as needed.

### (1) Configuration

A configuration and function of a semiconductor memory according to the embodiment will be described with reference to FIGS. 1 to 6.

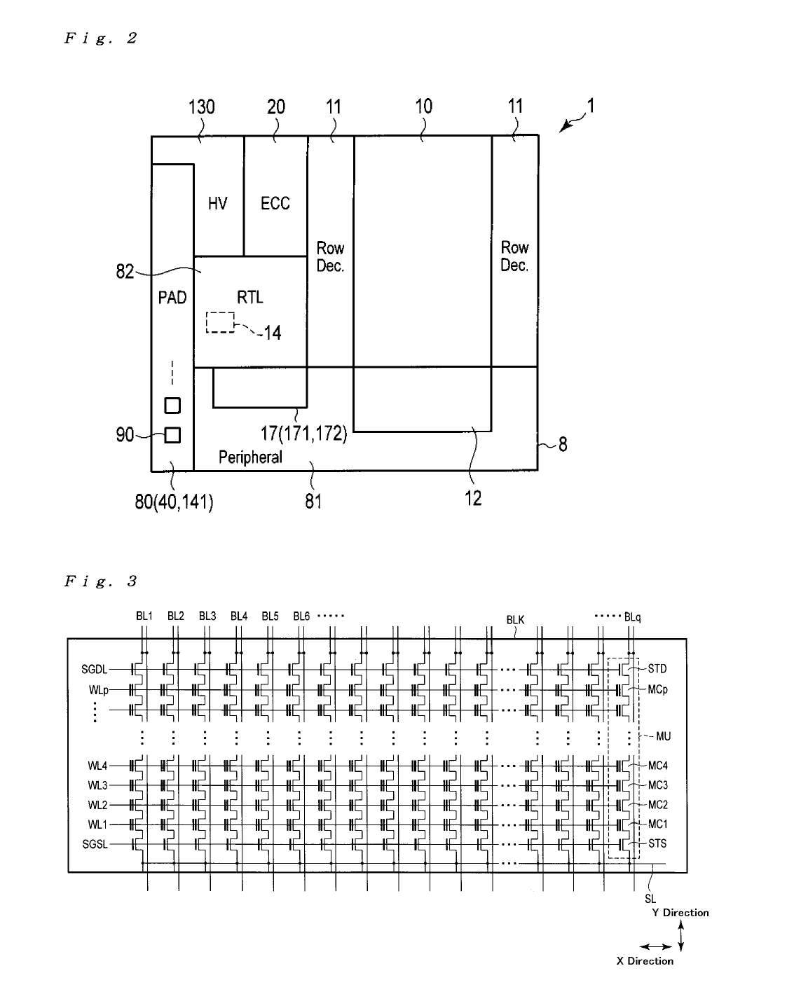

FIG. 1 is one example of a block diagram showing a main portion of the configuration of a semiconductor memory according to the present embodiment. FIG. 2 is a drawing showing one example of a chip layout of the semiconductor memory according to the embodiment.

The semiconductor memory according to the embodiment is, for example, anon-volatile semiconductor memory, and is a flash memory as a more specific example.

A flash memory 1 according to the embodiment receives a signal which is supplied from an external apparatus such as a memory controller 2 or a host device 2 which is provided in an outside of a chip of the flash memory 1 and transmits a signal to the memory controller 2 or the host device 2.

The flash memory 1 according to the embodiment forms a memory system with the memory controller/host device 2.

As shown in FIGS. 1 and 2, the flash memory 1 includes a row decoder (a row control circuit) 11 and a page buffer (a column control circuit 12). The row decoder 11 and the page buffer 12 are formed on a same chip (a semiconductor substrate) 8 on which the memory cell array 10 is formed and are disposed near the memory cell array 10.

FIG. 3 is an equivalent circuit diagram of the memory cell array 10. FIG. 3 shows a circuit configuration of the memory cell array 10 which is a NAND-type flash memory.

The memory cell array 10 includes multiple memory cells. The multiple (p) memory cells MC1 to MCp and two selection transistors STD, STS form multiple memory cell units MU. The multiple memory cell units MU is provided in the memory cell array 10.

Hereinafter, a memory cell MC represents the memory cells MC1 to MCp when there is no need for distinction, they are expressed as, and a selection transistor ST represents the selection transistors STD, STS when there is no need for distinction.

The memory cell MC is a field-effect transistor with a stacked gate structure having a charge accumulation layer (e.g., a floating gate electrode) provided via a gate insulating film on a semiconductor substrate and a control gate electrode laminated via an intermediate insulating film on the charge accumulation layer. The memory cell MC may have an MONOS (Metal Oxide Nitride Oxide Silicon) structure using a method of trapping electrons inside a nitride film (e.g., a silicon nitride film) as the charge accumulation layer.

In the memory cell unit MU, current paths of the memory cells MC adjacent to each other in a channel length direction of the transistor are serially connected with each other. The configuration in which the current paths are serially connected is referred to as a memory cell string. One end (a drain) of the memory cell string is connected with a source of the selection transistor STD, and the other end (a source) of the memory cell string is connected with a drain of the selection transistor STS.

Each control gate electrode of the memory cell MC in the memory cell unit MU is connected with any one of word lines WL1 to WLq. The gates of the selection transistors STD, STS are respectively connected with selection gate lines SGDL, SGSL. A drain of the selection transistor STD is connected with any one of bit lines BL1 to BLq. A source of the selection transistor STS has a common connection with a source line SL.

Hereinafter, a word line WL represents the word lines WL1 to WLp when there is no need for distinction, and a bit line BL represents the bit lines BL1 to BLq when there is no need for distinction. Also, a selection gate line SGL represents the selection gate lines SGDL, SGSL when there is no need for distinction.

The multiple memory cells MC connected with the same word line WL forms a control unit referred to as a page. Data is collectively written to and read from the memory cells MC on one page. The memory cells MC are formed such that data of multiple pages are erased collectively and a unit of erase is referred to as a block. Although only one block is shown in FIG. 3, the memory cell array 10 includes multiple blocks.

Each memory cell MC can store one-bit data which is associated with, for example, a change in a threshold voltage of the transistor depending on an amount of electrons in the charge accumulation layer. The flash memory can also store two-bit or more data in each memory call MC by subdividing a control of the threshold voltage.

In writing, reading, or erasing data, the row decoder 11 selects the word line WL and the selection gates SGD, SGS. Then, the row decoder 11 applies a voltage for performing each operation to the word line WL and the selection gate line SGL.

The page buffer 12 can hold data having a data size same as that of the page of the memory cell array 10. The page buffer 12 temporarily stores data for one page output from the memory cell array 10 when the data is read out and temporary stores data for one page to be written in the memory cell array 10 when the data is written.

As shown in FIG. 2, the row decoder 11 is provided adjacent to the memory cell array 10 in a row direction inside the chip of the flash memory 1. The page buffer 12 is provided adjacent to the memory cell array 10 in a column direction inside the chip.

In the embodiment, the memory cell array 10, the row decoder 11 adjacent to the memory cell array 10, and the page buffer 12 are also referred to as a memory core unit (or, a NAND core unit).

As shown in FIG. 1, in addition to the memory cell array 10 and the circuits 11, 12 near the memory cell array 10, the flash memory 1 includes a potential generation circuit 13, a sequencer 14, oscillators (OSC) 15, 16, a data transfer circuit 17, an ECC ((Error Checking and Correcting)) circuit 20, and an interface circuit 40. As shown in FIG. 2, these circuits 13, 14, 15, 16, 17, 20, 40 are provided in a peripheral circuit region 81 and a RTL (Register Transfer Level) circuit region 82 inside the same chip on which the memory cell array 10 (the memory core unit) is provided.

The potential generation circuit 13 generates a voltage to be used for writing, reading and erasing and applies the generated voltage to the circuits, such as the row decoder 11, inside the flash memory.

A circuit (hereinafter, referred to as a low-voltage generator) of the potential generation circuit 13, which generates a relatively low voltage (e.g., a driving voltage for the page buffer 12) is provided in the peripheral circuit region 81. As shown in FIG. 2, a circuit (hereinafter, referred to as a high-voltage generator) 130 of the potential generation circuit 13, which generates a relatively high voltage (e.g., a writing voltage or a reading voltage) is provided in a portion positioned in a corner region of the chip 8. For example, the high-voltage generator 130 is provided in a region (hereinafter, referred to as a high-voltage generator region 130) between the row decoder 11 and an end portion of the chip 8 in the row direction of the memory cell array 10.

The sequencer (the internal control circuit) 14 has a control of the entire operation of the flash memory 1. When the sequencer 14 receives various kinds of commands from the memory controller/host device 2, it executes a sequence of writing, reading and erasing the data based on the command. The sequencer 14 generates an internal control signal based on the sequence and controls an operation of the potential generation circuit 13 and the page buffer 12. The sequencer 14 also controls an operation of an ECC circuit 20 in an ECC operation. The sequencer 14 notifies an operational situation inside the flash memory 1 to the memory controller/host device 2.

The oscillator 15 generates an internal clock ICLK and supplies the sequencer 14 with this internal clock ICLK. The sequencer 14 operates in synchronization with the internal clock ICLK generated by the oscillator 15. The sequencer 14 generates a several clock signals from the internal clock ICLK and supplies the circuit in the flash memory 1 with the clock.

The oscillator 16 generates an internal clock ACLK according to an operation mode of the flash memory 1 and supplies the generated internal clock ACLK to the interface circuit 40. The internal clock ACLK is used as a reference clock (a control clock) for controlling the operations of the flash memory 1 in an operation mode to be described later and the memory controller/host device 2.

The oscillator 16 generates an internal clock ACLK_BN and supplies the generated internal clock ACLK_BN to the sequencer 14.

Hereinafter, for differentiation, the oscillator 16 generating the internal clock ACLK is also referred to as an ACLK generator 16.

For example, the sequencer 14 is provided in the RTL circuit region 82 and the ACLK generator 16 is provided in the peripheral circuit region 81. The oscillator 15 may be provided in the peripheral region 81 or may be provided in the RTL circuit region 82.

The data transfer circuit 17 controls data transfer between the circuits and between the data buses. The data transfer circuit 17 controls data transfer between the page buffer 12 and the ECC circuit 20 and data transfer between the page buffer 12 and the interface circuit 40. The data transfer circuit 17 includes multiple data storages (e.g., latch circuits) 171, 172. The data transfer circuit 17 controls multiple buses (data lines) IOBUS, ECC_RWD, DOUT.

The data transfer circuit 17 receives a control signal (and a clock) from the sequencer 14 and is controlled by the sequencer 14. The data transfer circuit 17 receives an internal clock (a control clock) CLKP_FB (=CLKP_FB<1:0>) from the page buffer 12.

For example, the data transfer circuit 17 is provided in the peripheral circuit region 81. It is preferable that the data transfer circuit 17 be provided in a region near a data input/output path (a data transfer path), specifically, in a region near the page buffer 12.

The interface circuit 40 is used for inputting or outputting a control signal (a command or a status) and data between the flash memory 1 and the memory controller/host device 2.

The interface circuit 40 includes an interface (I/F) 141. The interface 141 receives and transmits various signals, such as data, a control signal, a clock CLK, a command, an address ADR, and the like, from/to the external memory controller/host device 2 of the flash memory 1. One example of the control signal includes a chip enable signal/CE for enabling the flash memory 1 and the entire memory system, an address latch enable signal ALE for latching the address ADR, a command latch enable signal CLE for latching the command, a write enable signal/WE for enabling data writing, and a read enable signal/RE for enabling data reading.

The interface 141 transmits the command from the memory controller/host device 2 to the sequencer 14. The interface 141 supplies the internal clock (the control clock) CLKP (=CLKP<1:0>) to the page buffer 12. The interface 141 transmits the control signal (the selection signal) REOSELn to the data transfer circuit 17.

The interface 141 receives a signal TRANS_ONE from the sequencer 14. The interface 141 receives an internal clock ACLK from the oscillator 16.

The interface 141 mediates data transfer between the data transfer circuit 17 and the memory controller/host device 2.

In addition to the bus (the signal line) and the latch/buffer, the interface circuit 40 includes multiple pads as connection terminals between the flash memory and external devices. For example, as shown in FIG. 2, an arrangement region of the pad 90 (hereinafter, referred to as a pad region) 80 is provided in an end portion of the chip 8. The pad 90 is provided along a side of the chip 8.

The ECC circuit 20 performs ECC processing on the data. In reading data, the ECC circuit 20 detects and corrects an error in the data read out from the memory cell array 10. In writing data, the ECC circuit 20 creates a parity for the data to be programmed (hereinafter, referred to as a parity data or a parity bit). The ECC circuit 20 receives an internal clock (a control clock) ACLK_ECC from the sequencer 14.

The ECC circuit 20 includes an ECC buffer 201 and an ECC engine 202. The ECC buffer 201 is connected with the data transfer circuit 17 via the data bus ECC_RWD. The ECC buffer 201 temporarily stores data for the ECC processing (error detection/correction and parity creation). For example, the ECC buffer 201 is connected with the data transfer circuit 17 by the data bus having a 32-bit width. For example, the ECC buffer 201 supplies a clock to the interface circuit 40.

The ECC engine 202 performs ECC processing by using the data stored in the ECC buffer 201. The ECC engine 202 performs error correction on the data input to the ECC buffer 201 and outputs again the corrected data (Correct) to the ECC buffer 201. The ECC engine 202 creates a parity of the data input to the ECC buffer 201 and outputs again the data to which the created parity is added to the ECC buffer 201.

For example, the ECC circuit 20 has a correction capability of adding a parity data having n-bit (e.g., 4-bit) or more to one sector (=512 bytes).

As shown in FIG. 2, the peripheral circuit region 81 and the RTL circuit region 82 are disposed between the memory core units 10, 11, 12 and the pad region 80 on the chip 8 of the flash memory 1. The RTL circuit region 82 is provided in a region between the row decoder 11 and the pad region 80. For example, the peripheral circuit region 81 is provided in a region between the page buffer 12 and the pad region 80.

In the flash memory 1 according to the embodiment, the ECC circuit 20 is provided in (integrated into) the chip 8 on which the memory cell array 10 (the memory core units) is provided.

In the ECC circuit-mounted flash memory 1 (e.g., BENAND (a registered trademark)) according to the embodiment, the ECC circuit 20 is provided in a position far from the data transfer path between the pad region 80 and the page buffer 12.

For example, the ECC circuit 20 is provided in a region between the row decoder 11 and the high-voltage generation region 130. The ECC circuit 20 is surrounded by the row decoder 11, the high-voltage regeneration region 130, and the RTL circuit region 82. The RTL circuit region 82 is disposed between the ECC circuit 30 and the peripheral circuit region 81.

The high-voltage generation region 130 is provided in a region surrounded by the pad region 80, the RTL circuit region 82, and the row decoder 10. An area density (an integration degree) of a region near the high voltage generation region 130 and the row decoder 11 is sparse (low) as compared with an area density of the page buffer 12 and the peripheral circuit region 81.

With the miniaturization of a memory cell, the ECC circuit 20 tends to have a larger area (a circuit size) for improving a correction capability. As shown in FIG. 2, the ECC circuit 20 can be disposed in a region whose area density on the chip 8 is relatively low. Accordingly, an increase in the chip size or compression of another circuit region can be suppressed, so that the efficiency of the arrangement of the peripheral circuits can be improved. As a result, layout constraint on the chip can be alleviated and the ECC circuit 20 having a high correction capability can be disposed on the chip same as the chip on which the memory cell array 10 of the flash memory 1 is provided.

Also, the ECC circuit 20 can be provided in a position far from the data transfer path between the page buffer 12 and the pad region 80. Accordingly, the arrangement of wiring (the data bus and the clock bus) for transfer the data and clock can be simplified.

The flash memory 1 according to the embodiment is driven by selecting any one of an operation mode not using the ECC circuit 20 and an operation mode using the ECC circuit 20. Hereinafter, the operation mode not using the ECC circuit 20 is referred to as a NAND mode (or a NAND operation) and the operation mode using the ECC circuit 20 is referred to as a built-in ECC mode (or a built-in ECC operation).

Which one of the NAND mode and the built-in ECC mode to use to drive the flash memory 1 is set in such a manner that data showing any one of the operation modes is written in a ROM on the chip in a chip manufacturing process (before chip shipment). A user uses a flash memory driven in any one of the operation modes to build a memory system.

After that, the sequencer 14 controls an internal operation of the flash memory 1 in any one of the NADN mode and the built-in ECC mode based on a signal from the memory controller/host device 2.

In the flash memory according to the embodiment, data transfer is executed externally to the chip from the page buffer 12 in reading out the data by a FIFO (First-In First-out) method via one-stage buffer circuit (a pipe circuit) between the page buffer 12 and the data transfer circuit 17, and the data bus IOBUS.

The data transfer performed between the page buffer 12 and the ECC circuit 20 in the built-in ECC mode is executed via the data transfer circuit 17, the one-stage buffer circuit which is common with that in the NAND mode, and the data bus IOBUS.

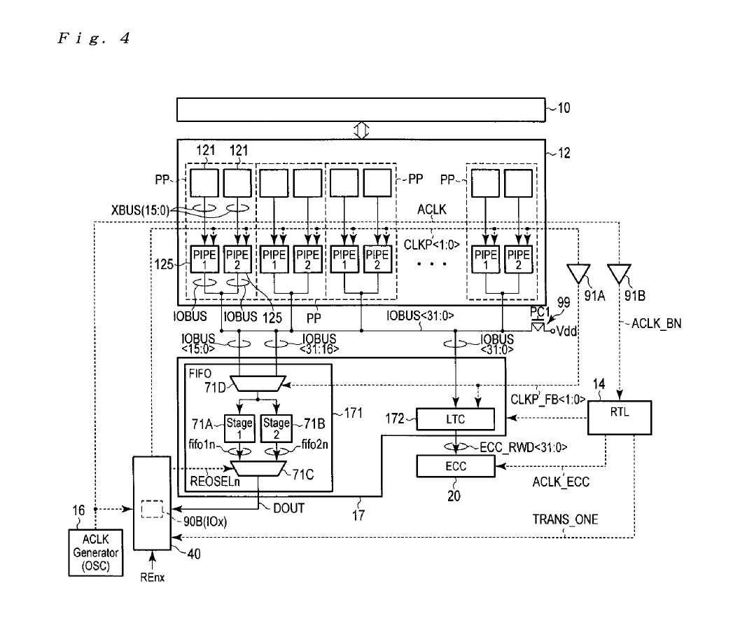

With reference to FIGS. 4 to 6, the configurations of the page buffer 12, the data transfer circuit 17, and the data bus, which are included in the flash memory 1 according to the embodiment, will be described.

FIG. 4 is a drawing schematically showing the circuit configurations of the page buffer 12, the data transfer circuit 17, and periphery thereof.

In the example shown in FIG. 4, the page buffer 12 includes multiple sense circuits 121 and multiple buffer circuits 125 corresponding to data transfer control units.

The sense circuits 121 detect the data stored in the memory cell array 10 and temporarily hold the data in reading out the data.

For example, in a case where one page is set to have a data size of 2 KB (2048 bytes), data of 32 B (256 bits) is dealt as a control unit for reading and writing the data in each sense circuit 121. As for the multiple sense circuits 121 in the page buffer 12, one sense circuit 121 is provided to support the data size of 32 B.

For example, multiple (here, 16) data buses XBUS<15:0>is connected with one sense circuit 121 and one buffer circuit 125. The buffer circuit 125 performs buffering on the data from the sense circuit 121 and outputs the data. Hereinafter, the data buses which are directly connected with the sense circuit 121 are referred to as local I/O lines XBUS<15:0>. Here, a local I/O line XBUS represents the local I/O lines XBUS<15:0> when there is no need for distinction.

The page buffer 12 is connected with the data transfer circuit 17 via multiple data buses IOBUS<31:0>.

For example, 32 data buses IOBUS<31:0> are used for the data transfer between the page buffer 12 and the data transfer circuit 17. Hereinafter, a data bus IOBUS represents the data buses (the data lines) IOBUS<31:0> when there is no need for distinction.

The data bus IOBUS is connected via the buffer circuit 125 with the local I/O line XBUS connected with the sense circuit 121.

Among the 32 data buses <31:0>, 16 data buses IOBUS<15:0> are connected with one buffer circuit (PIPE1) 125. The remaining 16 data buses IOBUS<31:16> are connected with the other buffer circuit (PIPE2) 125 different from the buffer circuit (PIPE1) connected with the 16 data buses IOBUS<15:0>. Hereinafter, the buffer circuit 125 between the data bus IOBUS and the local I/O line XBUS is also referred to as a pipe circuit (or a pipe) 125.

As described above, the flash memory according to the embodiment is driven in the two different operation modes. In the NAND mode, one sense circuit 121 and one pipe circuit 125 are selected and driven as a control unit for reading out the data. In the built-in ECC mode, two sense circuits 121 and two pipe circuits 125 are selected and driven at the same time as a control unit for reading out the data. Hereinafter, for clarifying the description, the two sense circuits 121 and the two pipe circuits 125 dealt as one control unit when driven in the built-in ECC mode are referred to as a circuit block PP. Note that each adjacent two of the sense circuit 121 and the pipe circuit 125 is shown as one circuit block PP in FIG. 4. However, the circuit block PP is not limited to the above configuration, and the circuit block PP may be formed by any pair of the sense circuit 121 and the pipe circuit 125 which are respectively connected with the different data buses <31:16>, <15:0>.

Multiple circuit blocks PP which is formed of the two sense circuits 121 and the two pipe circuits 125 is assigned to the 32 data buses IOBUS. The 32 data buses IOBUS are shared among the multiple circuit blocks PP.

The page buffer 12 and the data transfer circuit 17 (the data bus IOBUS) are connected with each other by the wired OR I/O line method and have a global connection. For example, each of first pipe units PU<0> of the one pile circuit (PIPE1) forming the circuit block PP has a common connection with the first data bus IOBUS. In this manner, the multiple pipe units PU is connected with one data bus IOBUS by the wired OR method, and the page buffer 12 and the data transfer circuit 17 (the data bus IOBUS) are globally connected with each other via the data bus IOBUS. Accordingly, the number of the data lines (I/O lines) between the page buffer 12 and the data transfer circuit (the data bus IOBUS) can be reduced.

Also, the local I/O line XBUS and the pipe circuit 125 are connected with each other with the local I/O line method. Thus, the number of the circuits and elements which are connected between the page buffer 12 and the data bus IOBUS can be reduced.

As a result of using these methods of connecting between the circuits (the data buses), a load of the data line during the operation of the flash memory is reduced. Thus, a higher operation and low-power consumption of the flash memory can be achieved.

The data buffer 17 is connected with the page buffer 12 via the 32 data buses IOBUS<31:0>.

The data transfer circuit 17 includes an FIFO circuit 171 as a data storage unit. The FIFO circuit 171 temporarily stores data from the page buffer 12 and outputs the stored data with a certain data size by the FIFO method to multiple (e.g., 16) data buses DOUT<15:0>. The data output from the data transfer circuit 17 is transferred to an outside of the chip of the flash memory 1 (e.g., the memory controller/host device 2) via the data bus DOUT and the interface circuit 40.

Hereinafter, the data bus DOUT<15:0> is referred to as an output bus DOUT<15:0> and an output bus DOUT represents the output buses (the data lines) DOUT<15:0> when there is no need for distinction.

The FIFO circuit 171 includes two latch circuits 71A, 71B, a selection circuit (a selector) 71C, and an MUX circuit (a multiplexer) 71D. The two lath circuits 71A, 71B are provided to respectively correspond to two stages. Each of the latch circuits 71A, 71B temporarily stores 16-bit data.

The latch circuits 71A, 71B inside the FIFO circuit 171 are connected with the 32 data buses IOBUS<31:0> via the MUX circuit 71D. Each of the latch circuits 71A, 71B is connected with both groups of the data buses IOBUS<31:16> and IOBUS<15:0> which are split by 16 via the MUX circuit 71D.

The MUX circuit 71D operates based on the internal clock CLKP_FB<1:0>. Also, the MUX circuit 71D connects the 16 data buses IOBUS<31:16> with one of the two latch circuits 71A, 71B and connects the remaining 16 data buses IOBUS<15:0> with the other of the two latch circuits 71A, 71B depending on a data holding state of the latch circuits 71A, 71B.

The one latch circuit 71A (here, in a first stage) is connected with the selector 71C via the 16 data buses fifo11n. The other latch circuit 71B (here, in a second stage) is connected with the selector 71C via the 16 data buses fifo12n.

The 16-bit data from the latch circuit 71A is output to the 16 data buses fifo11n and the 16-bit data from the latch circuit 71B is output to the 16 data buses fifo12n. The 16-bit data output from the latch circuits 71A, 71B is dealt as data for one stage.

A control signal REOSELn from the interface circuit 40 is supplied to the control terminal of the selector 71C. The selector 71C selects any one of the latch circuits 71A, 71B by using the control signal REOSELn as a selection signal and is connected with the output bus DOUT. Accordingly, the 16-bit data for one stage is output from the FIFO circuit 171 to the interface circuit 40 via the 16 output buses DOUT<15:0>.

The data input to the interface circuit 40 is output to the memory controller/host device 2 via the pad (IOx) 90A for data input/output.

The data from the page buffer 12 is transferred to the flash memory 1 by the FIFO method, so that the number of stages of the buffer circuit (the pipe circuits) between the page buffer 12 and the data transfer circuit 17 can be reduced. The data transfer with the FIFO method can simplify the configuration of the data transfer path between the page buffer 12 and the data transfer circuit 17. Consequently, the area of the buffer circuit is reduced and the operation and control of the data transfer can be simplified. In addition, the power consumption due to the buffer circuit can be also reduced.

Note that the FIFO circuit 17 may include three or more latch circuits.

The data transfer circuit 17 includes a latch circuit 172 as another data storage unit, which is different from the FIFO circuit 171. The latch circuit 172 is connected with the 32 data buses IOBUS<31:0> and temporarily stores the 32-bit data.

The latch circuit 172 is connected with the ECC circuit 20 via the 32 data buses ECC_RWD<31:0>. The latch circuit 172 outputs the stored data in a unit of 32-bit. The latch circuit 172 has a function as rebuffer (or a redriver) for data transfer to the ECC circuit 20.

As described above, the ECC circuit 20 is connected via the latch circuit 172 in the data transfer circuit 17 with the data bus IOBUS with which the page buffer 12 is connected and receives the 32-bit data output to the data bus IOBUS.

Hereinafter, for simplifying the description, the data bus ECC_RWD<31:0> connected with the ECC circuit 20 is referred to as an ECC bus ECC_RWD<31:0>, and a ECC bus ECC_RWD represents the ECC buses (the data lines) ECC_RWD<31:0> when there is no need for distinction.

The ACLK generator (the oscillator) 16 supplies the generated internal clock ACLK to the interface circuit 40. The internal clock ACLK generated by the ACLK generator 16 is rebuffered by the buffer 91B. The rebuffered internal clock ACLK_BN is supplied to the sequencer (the RTL circuit) 14.

The interface circuit 40 generates an internal clock CLKP<1:0> based on an external clock REnx or internal clocks ACLK, WEn_BN. For example, the internal clock CLKP<1:0> is generated in such a manner that the external clock REnx is rebuffered in the interface circuit 40. The internal clock CLKP<1:0> is supplied to each of the multiple pipe circuits 125 of the page buffer 12. The internal clock CLKP<1:0> from the interface circuit 40 is rebuffered by the buffer 91A. The rebuffered internal clock CLKP_FB<1:0> is supplied to the latch circuits 71A, 71B in the data transfer circuit 17.

The sequencer 14 generates an internal clock ACLK_ECC based on the clock ACLK_BN. The sequencer 14 supplies the internal clock ACLK_ECC to the ECC circuit 20. The sequencer 14 supplies the control signal TRANS_ONE to the interface circuit 40. When the control signal TRANS_ONE is supplied to the interface circuit 40, the interface circuit 40 generates another internal clock (e.g., a clock CLKP<1:0>) from the internal clock ACLK.

Note that a p channel-type field-effect transistor (hereinafter, expressed as a p-type transistor) 99 is connected with the data bus IOBUS. One end of a current path of the p-type transistor 99 is connected with the data bus IOBUS and the other end of the current path of the p-type transistor 99 is connected with a power supply terminal Vdd. A control signal PC1 is supplied to a gate of the p-type transistor 99. The p-type transistor 99 charges the data bus IOBUS. Note that a switch (e.g., an n channel-type field-effect transistor) for discharging the data bus IOBUS may be connected with the data bus IOBUS.

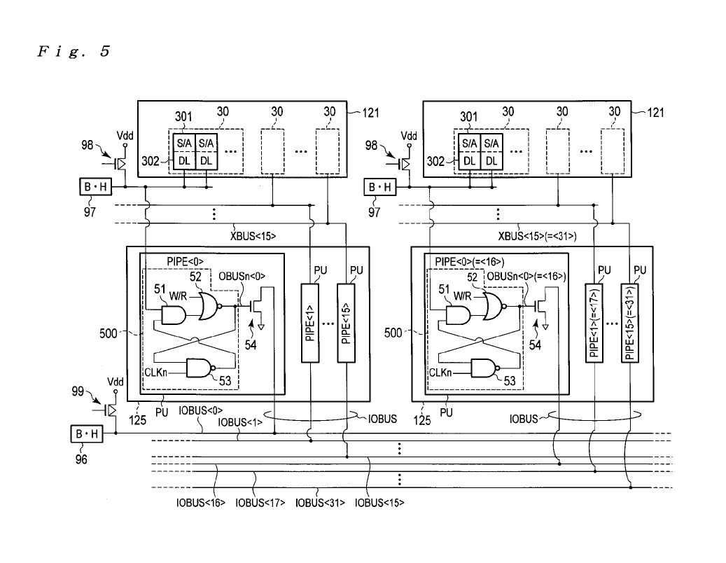

With reference to FIG. 5, the connection relationship between the page buffer 12 and the data bus IOBUS will be described.

FIG. 5 is a drawing schematically showing an internal configuration example of the page buffer 12 of the flash memory 1 according to the embodiment.

As described above, one sense circuit 121 performs control of reading/writing the data of 32 B. The 16 local I/O lines XBUS<15:0> are provided to the sense circuit 121 accepting the 32 B data.

The 32 B data is further divided into a unit of 2 B (16 bits) and then controlled.

In this case, the sense circuit 121 includes a circuit for performing a control (writing/reading) on the 2 B data size. Each sense circuit 121 includes multiple sense/latch units 30 accepting the 2 B data size.

One sense circuit 121 includes 16 sense/latch units 30. One sense/latch unit 30 is used for performing the control of writing/reading the 2 B data. Each sense/latch unit 30 is connected with one local I/O line XBUS.

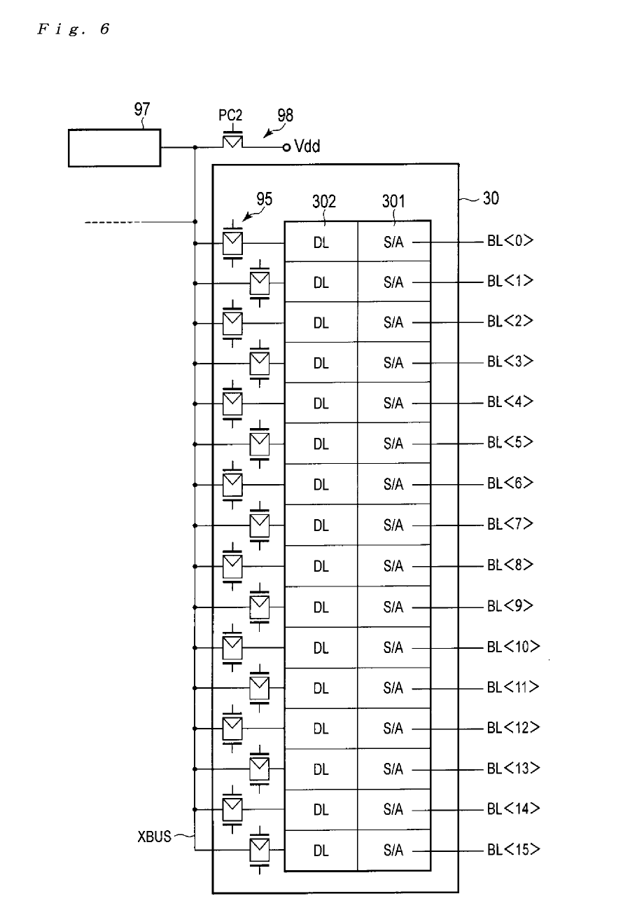

FIG. 6 is a schematic diagram showing an internal configuration of the sense/latch unit 30.

The sense/latch unit 30 includes multiple sense amplifiers 301 and multiple data latches 302. When the sense/latch unit 30 performs control on the 2 B (16 bits) data, the 16 sense amplifiers 301 and the 16 data latches 302 are provided in the sense/latch unit 30. For one sense/latch unit 30, 16 bit lines BL<0> to BL<15> are assigned.

Each sense amplifier 301 is connected with one bit line BL. The sense amplifier 301 detects and amplifies a potential change of the bit line BL based on the control of the sequencer 14. The sense amplifier 301 charges or discharges the bit line BL based on the control of the sequencer 14.

Each of the sense amplifiers 301 is connected with one bit line BL. However, one sense amplifier 301 may be connected with the adjacent even-numbered or odd-numbered two bit lines BL depending on the method of sensing the bit line BL. In this manner, when the sense amplifier 301 is shared by the two bit lines, the even-numbered or odd-numbered bit lines sharing the sense amplifier 301 are connected with the sense amplifier 301 at different timings which vary according to the operation.

One data latch 302 is provided corresponding to one sense amplifier 301. The data latch 302 holds one bit signal.

FIG. 6 shows an example in which one data latch 302 is provided for one sense amplifier 301. One or more data latches 302 may be provided for one sense amplifier 301 depending on which number of bits of data one memory cell stores data. Also, a latch for temporarily storing flag data or a verification result may be connected with the sense amplifier 301.

The sense amplifier 301 and the data latch 302 are connected with each other with a common line (not shown). The multiple sense amplifiers 301 and the multiple data latches 302 have common connections with the local I/O line XBUS via a common line and a transfer gate (referred to as a column selection switch) as a switch. For example, the transfer gate 95 is a MOS switch including a p channel-type field-effect transistor and an n channel-type field-effect transistor. When the data is read out, only the n channel-type transistor forming the transfer gate 95 is turned on. When the date is written, both the n channel-type and p-type transistors forming the transfer gate 95 are turned on.

The conduction state of the sense amplifier 301 and the data latch 302 with the local I/O line XBUS is controlled by the field-effect transistor 95. The sense amplifier 301 is connected with the local I/O line XBUS by a single end method.

For example, the 16 sense amplifier 301 and the 16 data latches 302 have common connections with the one local I/O line XBUS.

When the data is read out or written, the on/off of the field-effect transistor 95 is controlled so that the 16 sense amplifiers 301 and the 16 data latches 302 which are connected with the common I/O line XBUS are sequentially accessed one by one at a predetermined timing. In other words, one sense amplifier 301 and one data latch 302 among the 16 sense amplifiers 301 and the 16 data latches 302 are in conduction state with the local I/O line XBUS.

A field-effect transistor 98 and a bus hold circuit 97 are connected with each local I/O line XBUS.

One end of a current path of the p channel-type field-effect transistor (the p channel-type transistor) 98 is connected with the local I/O line XBUS and the other end of the current path of the p channel-type transistor 98 is connected with a power supply voltage Vdd. A control signal PC2 is input to a gate of the p channel-type transistor 98. The p channel-type transistor 98 is turned on based on the control signal PC2 to charge the local I/O line XBUS.

A bus hold circuit 97 is connected with the local I/O line XBUS for stabilizing a potential of the I/O line XBUS.

For example, when the data is read out, the data from the sense/latch unit 30 (each sense amplifier/data latch) is transferred to the local I/O line XBUS after the n channel-type transistor of the transfer gate 95 is turned on. When “1” data is transferred, the bus hold circuit 97 prevents a possibility that the “1” data is not transferred to the local I/O line XBUS according to a threshold Vth of the n-type transistor 95 (a possibility that it does not change to have a potential corresponding to the data).

Also, when the data is written, the data transfer from the data bus IOBUS to the local I/O line XBUS and the data transfer from the local I/O line XBUS to the sense/latch unit 30 are substantially performed together via a transfer gate (a MOS switch including the n channel-type/p channel-type transistors) between the buses (the data lines). In this case, even in a case where the transfer gate (not shown) between the data bus IOBUS and the local I/O line XBUS is turned off before the transfer gate 95 connecting between the local I/O line XBUS and the sense/latch unit 30 is turned off, the bus hold circuit 97 stabilizes the potential of the local I/O line XBUS, so that the data is transferred to the sense/latch unit 30.

Note that a p channel-type transistor 99 for precharge is connected with each data bus IOBUS<31:0> and a bus hold circuit 96 is connected for stabilizing the potential of the data bus IOBUS.

According to the operation of the flash memory 1, the predetermined number (e.g., 16 or 23) of local I/O buses XBUS are turned into a state connected with the data bus IOBUS via the pile circuit 125.

Each pile circuit 125 includes multiple pile units (buffers) PU<15> (=PU<31>) to <0> (=PU<16>). Here, a pipe unit PU represents the pipe units <15> to <0> when there is no need for distinction.

One pipe unit PU is connected with one local I/O line XBUS.

When one sense amplifier 121 and one pile circuit 125 are connected by the 16 local I/O lines XBUS<15:0>, the 16 pipe units PU are provided in one pile unit 125 respectively corresponding to the 16 local I/O lines XBUS<15:0>. Each pipe circuit 125 performs buffering on the data in a unit of 16 bits.

One pipe unit PU is provided between one local I/O line XBUS and one data bus IOBUS. One pile unit PU is connected with one data bus IOBUS. Each pipe unit PU is connected with the FIFO circuit 175 in the data transfer circuit 17 via the data bus IOBUS. The pipe unit PU is connected with the ECC circuit 20 via the data bus IOBUS and the data latch 175.

One pipe unit PU has a common connection with the 16 sense amplifiers 301 and the 16 data latches 302 via one local I/O line XBUS. When the pipe unit PU is driven, the pipe unit PU is turned in a state connected with one sense amplifier 301 and one data latch 302 forming an activated pair among the multiple sense amplifiers 301 and the multiple data latches 302.

Each pipe unit PU is formed by the buffer 500 and the field-effect transistor 54 and is connected with the data bus IOBUS with the wired OR method.

In the example shown in FIG. 5, the buffer 500 of the pipe unit PU<0> includes an AND gate 51, a NOR gate 52, and a NAND gate 53.

One input terminal of the AND gate 51 is connected with one local I/O line XBUS. The other input terminal of the AND gate 51 is connected with an output terminal of the NAND gate 53. An output terminal of the AND gate 51 is connected with one input terminal of the NOR gate 52. The input terminal connected with the local I/O line XBUS is used as one input cathode of the buffer 500.

An output terminal OBUSn of the NOR gate 52 is connected with one input terminal of the NAND gate 53. The output terminal OBUSn of the NOR gate is used as an output node of the buffer 500. A control signal CNT showing whether the running operation is writing or reading is supplied to the other input terminal of the NOR gate 52. An internal clock CLKn (or a clock CLK<1:0>) is supplied to the other input terminal of the NAND gate 53. The internal clock CLKn is substantially same signal as the internal clock CLK<1:0>.

In this manner, the buffer 500 of the pipe unit PU is formed of logical gate circuits 51, 52, 53.

Here, an output node OBUSn represents the output nodes OBUS<15:0> of the buffer 500 in each pipe unit PU when there is no need for distinction.

The output terminal OBUSn of the NOR gate 52 as an output node of the buffer 500 is connected with a gate of the n channel type field-effect transistor (the n-type transistor) 54. One end of the n channel-type transistor 54 is connected with the I/O line IOBUS. The other end of the current path of the n channel-type transistor 54 is connected with a ground terminal. The buffer 500 is in wired OR connection with the data bus IOBUS via the n-type transistor 54.

For example, during a period in which the internal clock CLKP is being in the “L” level, a voltage Vdd is applied via the p channel-type transistor 99 and the data bus IOBUS is precharged to the “H” level (the Vdd level).

When the output of the buffer 500 is in the “H (1)” level, the n channel-type transistor 54 is turned on. When the n channel-type transistor 54 is turned on, the data bus IOBUS is conducted with the ground terminal. When the data bus IOBUS is in a state of being charged, the signal level of the data bus IOBUS changes from the “H” level to the “L” level.

When the output of the buffer 500 is in the “L (0)” level, the n channel-type transistor 54 is turned off. When the n channel-type transistor 54 is turned off, the data bus IOBUS is electrically separated from the ground terminal and the signal level of the data bus IOBUS is maintained in the “H” level.

The pipe unit PU is synchronized with the internal clocks CLKn<1:0>, CLKP<1:0> and then driven.

For example, in one circuit block PP, 32 pile units PU are provided. According to an operation mode of the flash memory, the number of the pipe units selected and driven at the same time as an operation target differs.

In the NAND mode, the 32 pipe units PU forming one circuit block PP are divided into two groups and each group of the 16 pipe units <15:0> is controlled and driven as an independent control unit (a drive unit). Thus, the data from the page buffer 121 is transferred to the FIFO circuit 171 of the data transfer circuit 17 via the data bus IOBUS by every 16 bits.

In the built-in ECC mode, the 32 pipe units PU<15:0>, PU<31:16> are substantially controlled at the same time as a control unit (a drive unit). Accordingly, the data from the page buffer 121 is transferred to the ECC circuit 20 via the data bus IOBUS and the data transfer circuit 17 by every 32 bits.

For example, the data transfer using the pipe units PU and the FIFO circuit 171 is used for reading out the data from the memory cell array 10 to an outside thereof, and the data transfer performed when the data is written in the memory cell array 10 is executed by using a transfer gate (not shown) connected between the local I/O line XBUS and the data bus IOBUS.

Note that the configuration of the buffer 500 in the pipe unit PU, which is shown in FIG. 5, is just an example, and a buffer having another circuit configuration may be used for a pipe unit (a buffer circuit) depending on a control signal which is supplied to the buffer.

As described above, the flash memory according to the embodiment executes data transfer by using the wired OR I/O line method in which the page buffer circuit 12 and the data transfer circuit 17 are globally connected with each other and the FIFO method, so that an operation of the flash memory can be simplified and be speeded up. Accordingly, the flash memory according to the embodiment can have a more efficient design of a circuit or a chip layout.

### (b) Operation

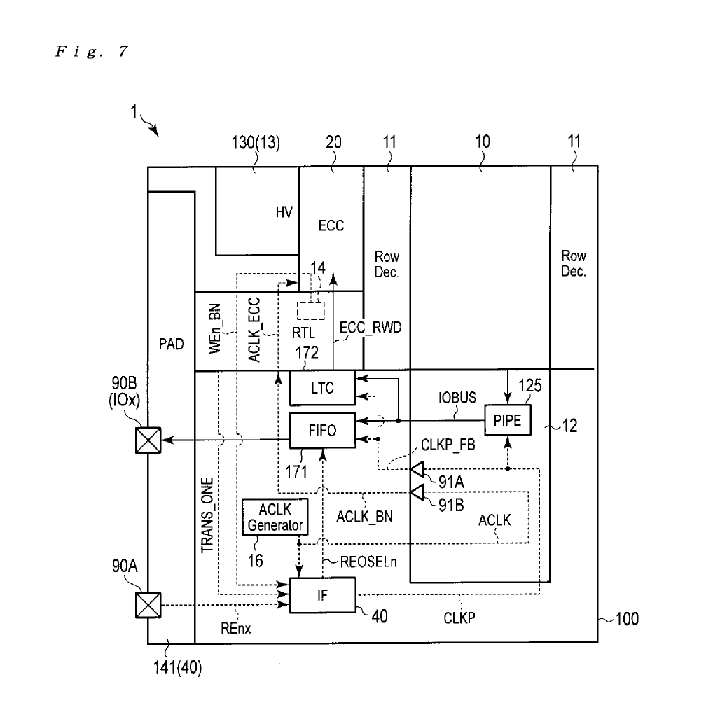

With reference to FIGS. 7 to 11, an operation of the flash memory according to the first embodiment shown in FIGS. 1 to 6 will be described. Hereinafter, the operation of the flash memory according to the embodiment is described by using FIGS. 1 to 6 as needed, in addition to FIGS. 7 to 11.

As described above, the flash memory 1 according to the embodiment is set to be driven in any one of the operation mode not using the ECC circuit 20 on a chip (the NAND mode) and the operation mode using the ECC circuit 20 (the built-in ECC mode) based on the ROM data on the chip.

FIG. 7 is one example of a schematic diagram showing a flow of a signal on the chip when the flash memory is being operated. In FIG. 7, the flow of data on the chip is shown by solid lines and the flow of clock (and control signal) on the chip is shown by dotted lines.

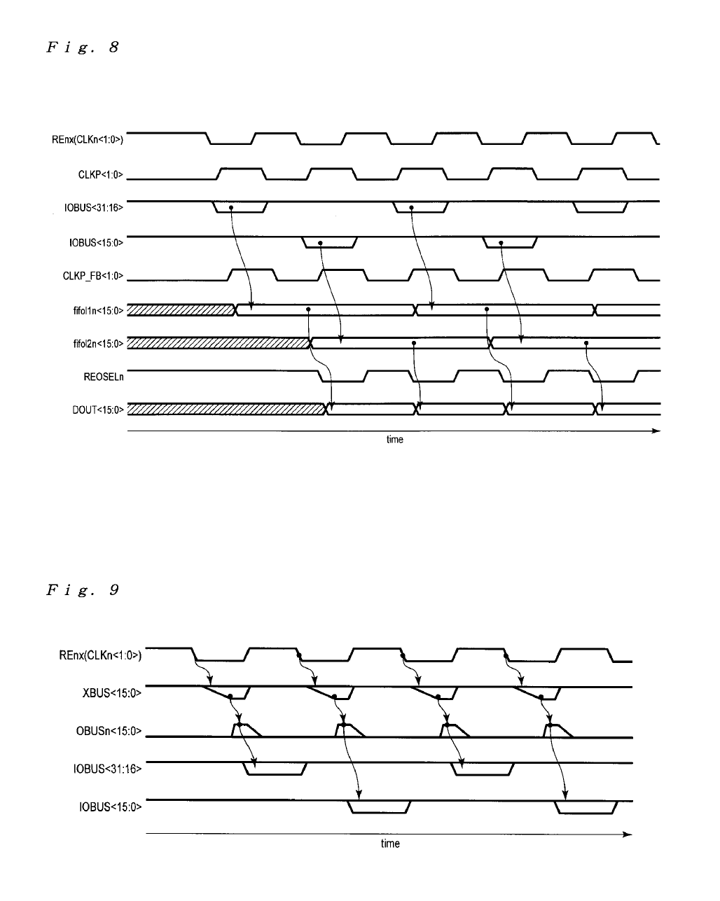

FIG. 8 and FIG. 9 show one example of timing charts of the operation of the flash memory according to the embodiment in the NAND mode.

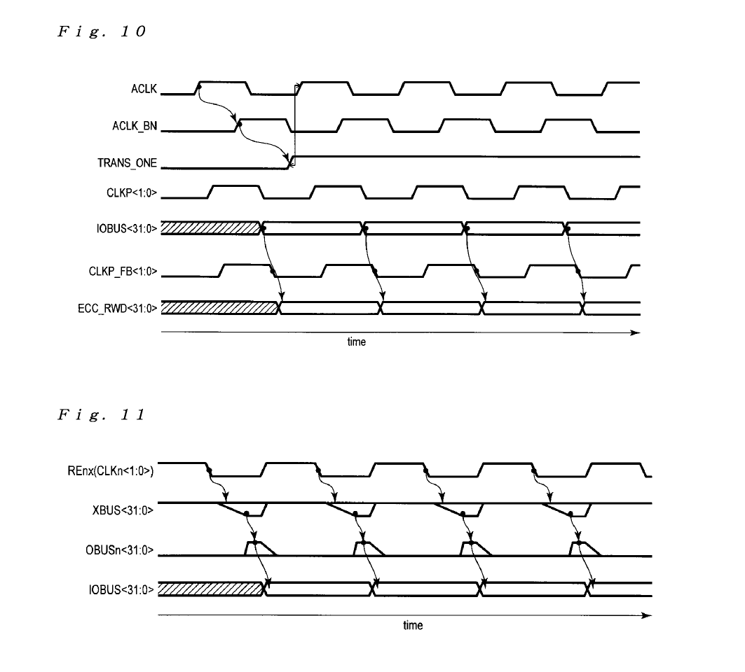

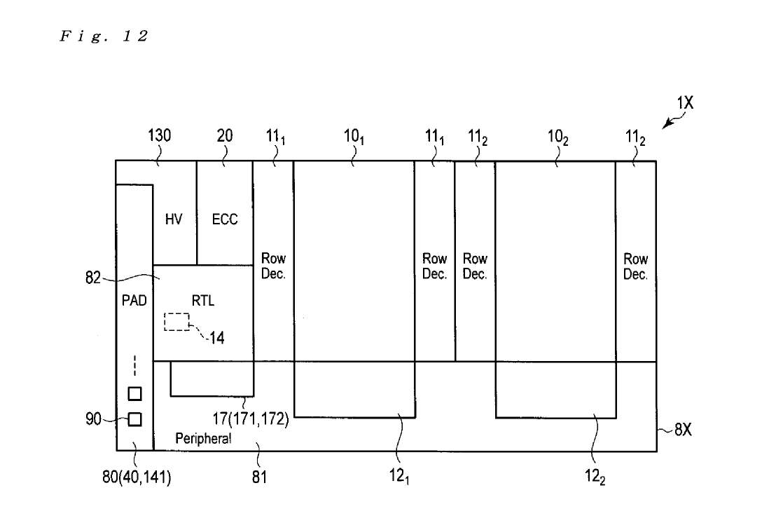

FIG. 10 and FIG. 11 show one example of timing charts of the operation of the flash memory according to the embodiment in the built-in ECC mode.

### <Operation 1>

With reference to FIGS. 7 and 8, the NAND mode in the flash memory according to the embodiment is described.

To read out data in the flash memory according to the embodiment in the NAND mode is described.

For example, in the flash memory 1 in FIG. 1, a control signal (a command) from the memory controller/host device 2 is input into an inside of the flash memory 1 via the interface circuit 40. An address ADR designated by the memory controller/host device 2 is input into the inside of the flash memory 1 via the interface circuit 40. When the data is read out, a reading command is transmitted to the flash memory 1 from the memory controller/host device 2.

The control signal based on the reading command and the address ADR is transferred to the sequencer (the RTL circuit) 14 from the interface circuit 40 (see, FIG. 1). The sequencer 14 controls the internal operation of the flash memory 1 based on the command, the control signal, and the control clock (the internal clock).

As shown in FIGS. 4, 7, and 8, an external clock REnx is supplied to the interface circuit 40 via the pad 90A. In the NAND mode, the interface circuit 40 generates an internal clock CLKP (=CLKP<1:0>) from the external clock REnx. The internal clock REnx and the internal clock CLKP<1:0> have phases opposite to each other.

To execute the operation corresponding to the command, the potential generation circuit 13 generates a potential (e.g., a driving voltage or a precharge voltage) which is applied to each circuit on the chip and a potential (e.g., a reading voltage, a non-selection voltage, or a writing voltage) which is applied to the word line based on the control signal from the sequencer 14.

For example, when a command is input into the interface circuit 40 and the sequencer 14, the data bus IOBUS and the local I/O line XBUS are precharged by turning on the transistors 98, 99 to which the control signals PC1, PC2 are supplied, thereby being in the “H” level. The internal clock CLKP from the interface circuit 40 is supplied to the page buffer 12.

When the data is read out, the potential from the potential generation circuit 13 is transferred to the selection word line and the non-selection word line by the row decoder 11. The data for one page stored in the page corresponding to the selection word line is output to the page buffer 12.

When the data reading operation is being performed in the NAND mode, a potential change of each bit line belonging to the selected page is detected and amplified by each sense circuit 121 and each sense amplifier 301 by a well-known operation. Based on the amplitude of the detected potential change, data of each memory cell is determined. The one-bit data is stored in each sense amplifier 301 and the data latch 302, and is stored for each 2 B data size in each sense/latch unit 31 in the sense circuit 121. The 32 B data is stored in each of the sense circuits 121. Accordingly, for example, the 2 KB data is output from the memory cell array 10 to the page buffer 12.

As shown in FIG. 8, the data transfer from the page buffer 12 to the data bus IOBS is started in synchronization with the external clock REnx and the internal clock CLKP<1:0>. Then, after the data is output to the data bus IOBUS, the data output to the data bus IOBUS via the buffer circuit (pipe) 125 is successively stored in the data transfer circuit 17 during a period in which the external clock REnx is in the “L” level (the internal clocks CLKP<1:0>, CLKP_FB<1:0> are in the “H” level).

In the NAND mode, the data in a unit of 16 bits is transferred from the page buffer 12 to the data transfer circuit 17 via one pipe circuit 125 which is sequentially selected.

Here, FIG. 9 and FIG. 8 are used for specifically describing the data transfer from the local I/O line XBUS to the data bus IOBUS via the pipe unit PU in the NAND mode. FIG. 9 shows one example of a timing chart of the data transfer from the local I/O line XBUS to the data bus IOBUS.

As shown in FIGS. 8 and 9, the data transfer from the page buffer 12 to the data bus IOBUS is executed for each predetermined data size (a bit width) during periods in which the external clock REnx is in the “L” level and in which the internal clock CLKP<1:0> is in the “H” level (a period before which the data transfer from the data bus IOBUS to the data lines fifo11n, fifo12n in the data transfer circuit 17 is started).

The internal clocks CLKP, CLKn<1:0> are input to each buffer circuit (pipe unit) 121 in the page buffer 12. One pair of the sense circuit 121 and the buffer circuit 125 is activated and is connected with the data bus IOBUS by the control of the sequencer 14. When the pair of the sense circuit 121 and the buffer circuit 125 is being activated, the remaining sense circuits 121 and buffer circuits 125 are electrically separated from the data bus IOBUS by the control of the sequencer 14.

As shown in FIG. 9, the data is output to the local I/O line XBUS at timing synchronized with the external clock REnx, more specifically, at timing synchronized with the trailing edge of the internal clock CLKn<1:0> corresponding to the external clock REnx.

For example, in the NAND mode, 16-bit data is transferred as one data set (a data unit or a data block) to the 16 local I/O XBUS<15:0> which are selected from the selected sense amplifiers/data latches 301, 302. One-bit data is output to one local I/O line XBUS.

In the embodiment, as shown in FIG. 6, one transfer gate (the n channel-type transistor) 95 is turned on in each local I/O line XBUS, and one sense amplifier 301 and the data latch 302 are activated. Accordingly, one-bit data is output to each local I/O line XBUS. A unit of 16 bits (a data unit) is formed by the one-bit data in the 16 local I/O lines XBUS<15:0>.

When the local I/O line XBUS is precharged, the local I/O line XBUS maintains the charged state (the “H” level) or becomes a discharged state (the “L” level) according to the data output from the sense amplifier 301 and the data latch 302. A change in the potential level of the precharged local I/O line XBUS is associated with the data output from the sense amplifier 301 and the data latch 302.

When the signal level of the precharged local I/O line XBUS transitions from the “H” level to the “L” level, in the flash memory according to the embodiment, the sense/latch unit 30 and the pipe unit PU are connected with each other by the local I/O line method. Accordingly, a load caused in the data line (a parasitic resistance and a parasitic capacitance) is reduced and the potential level of the local I/O line XBUS transitions from the “H” level to the “L” level with a relatively faster speed.

The pipe circuits (the buffer circuits) 125 connected with the 16 selected locals I/O line XBUS are activated by the sequencer 14. In each of the activated pipe circuits 23, the data from the sense amplifier 301 and the data latch 302 are supplied to the pipe unit PU corresponding to one of the local I/O line XBUS. In the 16-bit data output at the same time, one-bit data is supplied to each of the pipe units PU are wired-OR connected to the data bus IOBUS.

When the data is output from the local I/O line XBUS to the pipe circuit 125, a signal in the “0 (L)” level corresponding to the clock REnx (CLKn<1:0>) is input to the input terminal of the NAND gate 53 of the buffer 500 of the pipe unit PU in FIG. 5.

When the “0” level signal is input into one input terminal of the NAND gate 53, the output of the NAND gate 53 becomes a signal having the “1 (H)” level without depending on the signal level of another input terminal of the NAND gate, in other words, an output node (an output terminal of the NOR gate) of the buffer 500. Note that in the example in FIG. 9, an initial state of the potential level of the node OBUSn of the buffer 500 is set to the “0 (L)” level.

The signal output from the output terminal of the AND gate 51 is a result of an AND operation of the one-bit data (a “1” or “0” signal level) output to the local I/O line XBUS and the “1” level from the NAND gate 53. This signal output is an input node of the buffer 500 of the pipe unit PU.

When the data output to the local I/O line is “1”, the output of the AND gate 51 becomes “1”. When the data output to the local I/O line XBUS is “0”, the output of the AND gate 51 becomes “0”. Accordingly, when the buffering is performed by the pipe unit PU, the signal level same as that of the data output to the local I/O line XBUS becomes an output of the AND gate 51.

When the data is read out, a control signal CNT having the “0(L)” level showing the reading operation is input to the input terminal of the NOR gate of the buffer 00 of the pipe unit PU.

The signal output from the output terminal of the NOR gate 52 corresponding to an output node OBUSn of the buffer 500 is a result of a NOR operation of the outputs of the AND gate 51 (the data of “1” or “0” output to the local I/O line XBUS) and the control signal CNT having the “0” level.

When the output of the AND gate has the “1” level during reading out the data (when the data output to the local I/O line is “1”), the result of NOR operation performed by the NOR gate 52 is “0”. In this case, the potential of the output node OBUSn of the buffer 500 becomes the “L” level.

On the other hand, when the output of the AND gate 51 is the “0” level during reading out the data (when the data output to the local I/O line XBUS is “0”), the result of the NOR operation performed by the NOR gate 52 is “1”. In this case, the potential of the output node OBUSn of the buffer 500 becomes the “H” level.

As described above, when the buffering is performed by the pipe unit PU, the signal level opposite to that of the data output to the local I/O line XBUS becomes a potential level (an output of the NOR gate 52) of the output node OBUSn of the buffer 500.

The n channel-type transistor 54 whose gate is connected with the output node OBUSn is turned on or off according to the potential level of the output node of the buffer 500.

When the output of the buffer 500 is in the “L (0)” level, the n channel-type transistor 54 is turned off, and the data bus IOBUS is electrically separated from the ground terminal by the n channel-type transistor 54 in the off state. As a result, the potential of the data bus IOBUS to which the potential Vdd is applied is in the “1 (H)” level, which is the same signal level with that of the “1” data output to the local I/O line XBUS corresponding to that data bus IOBUS.

On the other hand, when the output of the buffer 500 is in the “1 (H)” level, the n channel-type transistor 54 is turned on, and the data bus IOBUS is turned into a state connected with the ground terminal by the n-type transistor 54 in the on state. As a result, the potential of the data bus IOBUS is in the “L (0)” level, which is the same signal level with that of the “0” data output to the local I/O line XBUS corresponding to that data bus IOBUS.

Accordingly, 16-bit data is output to the 16 IOBUS<31:16> corresponding to the selected 16 local I/O lines XBUS<15:0> among the 32 IOBUS<31:0> via the pipe circuit (PIPE1) 125.

In this manner, the data from the sense circuit 121 is transferred to the data bus IOBUS via the pipe unit 16 of the one-stage pipe circuit 125.

For example, after the data is output to the data bus IOBUS, the signal level of the output node OBUSn of the buffer 500 of the pipe unit PU becomes the “H” level. Note that the signal level (the potential level) of the output node OBUSn of the buffer 500 becomes the “L” level by controlling the signal level of the control signal CNT.

As described above, the 16-bit data is transferred from the page buffer 12 to the data bus IOBUS<31:16> via the pipe unit connected with the data bus IOBUS in the wired OR method.

In parallel with the output of the data from the local I/O line XBUS to the data bus IOBUS, as shown in FIG. 7, the internal clock CLKP from the interface circuit 40 is rebuffered by a buffer 91A provided in a clock transmission path (a clock bus, a clock line) in the page buffer 12. The rebuffered internal clock CKLP_FB (=CLKP_FB<1:0>) is supplied to the FIFO circuit 171 in the data transfer circuit 17. The FIFO circuit 171 is driven and controlled by the rebuffered internal clock CLKP_FB. The FIFO circuit 171 fetches the data output to the data bus IOBUS in synchronization with the rebuffered internal clock CLKP_FB, and transmits the data to the output bus DOUT in synchronization with the control signal (the selection signal) REOSELn.

Accordingly, the internal clocks CLKP, CLKP_FB are transmitted on the chip in the direction same as the direction in which the data output from the memory cell array 10 flows (PIPE 125 to FIFO 171, LTC 172 in FIG. 7). Also, the length of the clock line changes along with the length of the data line. As a result, to design the timing of the flash memory 1 becomes relatively easy.

As shown in FIG. 8, at the timing synchronized with the internal clock CLKP_FB<1:0>, the data output to the data bus IOBUS<31:16> is stored in the latch circuit 71A of the FIFO circuit 71 via a MUX circuit 71D.

For example, the data output to the data bus IOBUS<31:16> is stored in the latch circuit 71A during a period in which the internal clock CLKP_FB<1:0> is in the “H” level (or in synchronization with the transition from the “L” level to the “H” level). Then, the stored 16-bit data is held as data for one stage (the first data) on a signal line fifo11n<15:0> between the latch circuit 71A and the selector 71C.

Note that the sequencer 14 and the MUX circuit 71D may control whether to store the first data in the latch circuit 71A or the latch circuit 71B, and the first data may be stored in the latch circuit 71B.

At the timing when the control signal (the selection signal) REOSELn from the interface circuit 40 changes from the “H” level to the “L” level, the data stored in the latch circuit 71A of the FIFO circuit 171 is output to the output bus DOUT<15:0> from the FIFO circuit 171 via the data line fifo11n<15:0> and the selector 71C. For example, during a period of one cycle of the control signal REOSELn, the 16-bit data corresponding to the one stage is output to the output bus DOUT<15:0>.

The data is transferred between the page buffer 12 and the FIFO circuit 171 via the 16 data bus IOBUS, and the 16-bit data different from the data stored in the FIFO circuit 171 (the second data) is output to the output bus DOUT<15:0> as similar to the above-described operation shown in FIG. 9 at timing when the clocks REnx(CLKn<1:0>, CLKP<1:0>) transition from the “H” level to the “L” level.

The 16-bit data from the local I/O line XBUS is buffered by the pipe unit PU, and is output to the data bus IOBUS<15:0> via the pipe circuit (PIPE2) 125 at the timing when the clocks REnx (CLKn<1:0>, CLKP<1:0>) transition from the “L” level to the “H” level.

The second data in a unit of 16 bits is output to the latch circuit 71B of the FIFO circuit 171 via the MUX circuit 71D with the operation parallel with the operation in which the first data in a unit of 16 bits, which is stored in the FIFO circuit 171, is output to the output BUS DOBUS. The second data is stored as data for a second stage in the latch circuit 71B connected with the data bus IOBUS<15:0> during a period in which the internal clock CLKP_FB<1:0> is in the “L” level. Then, the data is stored in the second stage storage in the latch circuit 71B (the data of the data line fifo12n<15:0>) without being output by the selector 71C until the output of the data in the first stage of the data line fifo11n<15:0> is completed.

Then, after the output of the data line fifo11n<15:0> has been completed, the data for the second stage is output to the output bus DOBUT via the data line fifo12n<15:0> and the selector 71C during a period in which the signal level of the control signal REOSELn is in the “L” level (or at timing of the transition from the “H” level to the “L” level).

The transfer of the data in a unit of 16 bits from the page buffer 12 to the data transfer circuit 17 is sequentially executed via the pipe circuit 125 which is selected (activated) one by one. Then, the data in a unit of 16 bits is successively output by the FIFO method to the output bus DOUT connected with the I/O pad 90B.

With this, in the data reading in the NAND mode, the data for one page stored in the flash memory 1 is transferred to an external memory controller/host device 2 of the flash memory 1.

Note that in the NAND mode, the data output to the data bus IOBUS is not stored in the latch circuit 172 connected with the ECC circuit 20.

In the embodiment, the data transfer is performed by using the FIFO method, so that the number of stages in the buffer circuit in the data bus can be reduced and the timing of the operation can be easily designed.

In the embodiment, the 32 data buses <31:0> are controlled by being divided into two groups in the NAND mode. The data is alternately output to each of the 16 divided data buses <31:16>, <15:0>. In this manner, the data buses IOBUS are driven in a state of being divided, so that the NAND mode and the built-in ECC mode can be present at the same time on the chip of the flash memory.

As described above, the data reading operation in the NAND mode is executed in the flash memory according to the embodiment.

The data wiring operation in the flash memory according to the embodiment in the NAND mode is executed as follows. Note that as for the data writing operation, the operation substantially same as the data reading operation is described as needed.

When the data is written, a wiring command, an address, and data to be written (e.g., data for one page) are input to the interface circuit 40 of the flash memory 1 from the memory controller/host device 2 (see FIG. 1).

Based on the writing command, a control signal (a writing clock) for writing data in the NAND mode is generated by the sequencer (the RTL circuit) 14.

The data to be written is transferred from the interface circuit 40 to the data transfer circuit 17 based on the command and the control signal and then stored in the data transfer circuit 17.

The data stored in the data transfer circuit 17 is transferred to the page buffer 12 via the data bus IOBUS. For example, the data transfer from the data bus IOBUS to the local I/O line XBUS is performed via the transfer gate (not shown).

The one-bit data output to each local I/O line XBUS is stored in the sense amplifier 301 and data latch 302 of the sense/latch unit 30. When the data is written in the NAND mode, the data output from the data transfer circuit 17 to the data bus IOBUS may be executed in a unit of 16 bits or may be executed in a unit of 32 bits.

The data transfer with a predetermined data size is successively repeated until the transfer of the data for one page to the page buffer 12 is completed.

The potential of the bit line BL is controlled by the sequencer 14 corresponding to the data to be written and a writing voltage is applied to the word line corresponding to the selected page. Accordingly, the data for one page stored in the page buffer 12 corresponding to the data to be written is written on a selected page in the memory cell array 10 by a well-known operation (a writing method).

As described above, the operation of data wiring in the NAND mode in the flash memory according to the embodiment is executed.

With the above-described each operation, the flash memory 1 according to the embodiment is driven in the NAND mode.

### <Operation 2>

With reference to FIGS. 10 and 11, the built-in ECC mode in the flash memory according to the embodiment is described. Here, an operation of the flash memory in the built-in ECC mode is described by using FIGS. 1 to 7 as needed. Note that, the operation which is common in both the NAND mode and the built-in ECC mode is described as needed.

As shown in FIGS. 4, 7, and 10, in the built-in ECC mode, an internal clock ACLK is generated on the chip 8 of the flash memory 1 by the ACLK generator (the oscillator) 16 based on a control signal from the memory controller/host device 2.

The generated internal clock ACLK is supplied to the interface circuit 40 and the page buffer 12.

The internal clock ACLK is rebuffered by the buffer 91B in the page buffer 12 in a clock line from the ACLK generator 16 to the sequencer 14. The rebuffered internal clock ACLK_BN is supplied to the sequencer 14.

The internal clock CLKP is generated by the interface circuit 40 using the internal clock ACLK. The internal clock CLKP is supplied to the page buffer 12.

Based on the internal clocks ACLK, ACLK_BN, the internal clock ACLK_ECC for the ECC circuit 20 is generated by the sequencer 14.

In the built-in ECC mode, a control signal TRANS_ONE is generated by the sequencer 14 based on the supplied internal clock ACLK_BN. For example, the control signal TRANS_ONE is generated at timing when the internal clock ACLK_BN is input and the internal clock ACLK_BN transitions to the “H” level. The control signal TRANS_ONE is input to the interface circuit 40.

The control signal TRANS_ONE has the first signal rise time (transition from the “L” level to the “H” level) at timing before the second rising time of the internal clock ACLK (transition from the “L” level to the “H” level).

The signal rise times (the transition to the “H” level) of the internal clock ACLK and the control signal TRANS_ONE become a rate-limiting factor of starting the operation of the ECC circuit 20 (an ECC processing capable state). Therefore, to make the operation faster, it is preferable that the first rise time of the control signal TRANS_ONE be set prior to the second rise time. It is preferable that the ECC circuit 20 be disposed on the same chip 8 as the chip on which the memory cell array 10 so that the ECC circuit 20 is separated from the data transfer path in a range. Because of it is not affected by a delay due to the patristic resistance and parasitic capacitance of the wire length considering of the transition timing of the clock signal which limits the operation into consideration.

FIG. 11 shows a timing chart of the data transfer from the local I/O line XBUS to the data bus IOBUS in the built-in ECC mode.

As shown in FIG. 11, in the ECC mode, two pipe circuits (buffer circuits) 125 (32 pipe units) forming one circuit block PP are simultaneously driven, and 32-bit data is transferred from the 32 local I/O lines XBUS<31:0> to the 32 data buses IOBUS<31:0> via each pipe unit PU.

As for 32 pairs of the local I/O lines XBUS<31:0> and the data buses IOBUS<31:0>, one-bit data output to each local I/O line XBUS<31:0> is transferred to each data bus IOBUS via one pipe unit PU. Accordingly, data transfer in a unit of 32 bits to the data bus IOBUS is executed.

Note that an operation of each pipe unit PU for transferring the data from the local I/O line XBUS to the data bus IOBUS is same as that of the NAND mode, except that the number of the pipe units which are simultaneously driven is different, and the description thereof is omitted.

The 32-bit data output to the data bus XBUS<31:0> is stored in the latch circuit 172 for the ECC circuit 20, which is in the data transfer circuit 70, in synchronization with the clock CLKP_FB<1:0>.

For example, the 32-bit data is stored in the latch circuit 172 at timing in which the internal clock CLKP_FB<1:0> transitions from the “H” level to the “L” level, and is output to the data bus (ECC bus) ECC_RWB<31:0> between the data transfer circuit 17 and the ECC circuit 20. Note that one-bit data is output in parallel to one data bus ECC_RWB when the data to the ECC bus ECC_RWB is output from the latch circuit 172.

As similar to the above-described NAND mode, in the built-in ECC mode, the flow (the transmission direction) of the clock is also same as the flow of the data on the chip (PIPE 125 to FIFO 171, LTC 172).

One sector (512 bytes) data is formed by the 32-bit data sequentially output to the ECC bus ECC_RWB. Based on the parity data created when the data is written, it is validated that the formed one sector data contains an error due to the ECC circuit 20.

When an error is present in the one sector data transferred to the ECC circuit 20 in a unit of 32 bits, the ECC circuit 20 corrects an error in the data. The error-corrected data is transferred, for example, from the ECC circuit 20 to the page buffer 12 via the ECC bus ECC_RWB<31:0> and the data bus IOBUS<31:0>. Note that when there is no error in one sector data, the correction processing is not executed.

The data after the ECC processing by the ECC circuit 20 is transferred from the page buffer 12 to the data transfer circuit 17 in a unit of 16 bits. Then, as similar to the above-described NAND mode, the data is output to the output bus DOUT by the FIFO method.

In this manner, in a case where the flash memory according to the embodiment is driven in the built-in ECC mode, the data in a unit of 32 bits is transferred from the page buffer 12 to the ECC circuit 20 via the data bus IOBUS which is common with the data bus IOBUS used in the NAND mode.

Note that the data after the ECC processing by the ECC circuit 20 may be directly transferred from the ECC circuit 20 to the interface circuit 40 without going through the page buffer 12 or the data transfer circuit 17.

As described above, the operation of reading the data in the built-in ECC mode is executed in the flash memory according to the embodiment.

To write the data in the flash memory according to the embodiment in the built-in ECC mode is executed as follows. Note that the writing operation in the built-in ECC mode, which is substantially same as the above described operation, is described as needed.

When the data is written, a command, an address, and data to be written (e.g., data for one page) are input from the memory controller/host device 2 to the interface circuit 40 in the flash memory 1.

As similar to the data reading operation in the built-in ECC mode, an internal clock ACLK is generated by the ACLK generator 16.

As shown in FIG. 7, based on the command, a control signal (writing clock) WEn_BN for writing data in the built-in ECC mode is generated by the sequencer 14. The control signal WEn_BN is converted by the interface circuit 40 to an internal clock CLKP.

In this manner, in the built-in ECC mode, the control signal (internal signal) for writing data is generated as a signal independent from the control signal for reading data. Accordingly, the length of the clock bus can be changed (adjusted) corresponding to the length of the data bus.

The data to be written is transferred from the interface circuit 40 to the page buffer 12 via the data bus IOBUS and the data transfer circuit 17 based on the clocks ACLK, CLKP (CLKP_FB) and the control signal WEn_BN. Then, the 32-bit data is transferred from the page buffer 12 to the activated latch circuit 172 and stored in the latch circuit 172. Note that the data transfer from the interface circuit 40 to the ECC circuit 20 may be directly performed from the data transfer circuit 17 to the ECC circuit 20.

Then, the internal clock ACLK_ECC is supplied to the ECC circuit 20, so that the ECC circuit 20 is activated based on the clock ACLK_ECC. As similar to the data reading in the built-in ECC mode, when the data is written in the built-in ECC mode, the data in a unit of 32 bits is also transferred between the latch circuit 172 of the data transfer circuit 17 and the ECC circuit 20.

The ECC circuit 20 generates parity data (a parity bit) for the data supplied from the data bus ECC_RWD. For example, a 4-bit parity bit is added to the 512 B data. When one page is 2 KB, for example, the data for one page is divided into 4 sectors to control the ECC processing (e.g., creation of parity data or error correction).

The data to be written and the parity data are transferred from the data transfer circuit 20 to the page buffer 12 via the data bus IOBUS and the data transfer circuit 17. In the data transfer from the data transfer circuit 17 to the page buffer 12 in data writing, for example, the data in a unit of 32 bits is output to the local I/O line XBUS from the data bus IOBUS via the transfer gate (not shown). The data output to the local I/O line XBUS is stored in the sense amplifier 301 and the data latch 302 in the sense/latch unit 31.

The data in a unit of 32 bits is sequentially transferred to the ECC circuit 20, and the parity data for the data to be written is repeatedly executed for a predetermined data size.

Then, the parity data for the data for one page is created. After the data for one page is gathered in the page buffer 12, the data for one page is written on a selected page in the memory cell array 10 by a well-known operation.

As described above, the operation of writing data in the built-in ECC mode is executed in the flash memory 1 according to the embodiment.

With the above-described operations, the flash memory 1 according to the embodiment is driven in the built-in ECC mode.

### (c) Effects

As described above, the flash memory according to the embodiment is driven in the two operation modes.

In the flash memory according to the embodiment and the operations (the control method/the data transfer method) thereof, sizes of data to be output from the page buffer 12 to the data bus IOBUS differ based on the operation modes, but the operations of the transfer data from the page buffer 12 to the data bus IOBUS are same.

When the data is read out in the flash memory 1 according to the embodiment, the data transfer between the page buffer 12 and the data transfer circuit 17 via the data bus IOBUS is executed by the first-stage buffers (pipes) 125, PU on the transmission side (the output side) and the first-stage latch circuits 71A, 71B, 172 of the data transfer circuit 17 on the reception side (the input side).

When the flash memory 1 according to the embodiment is driven in the NAND mode, the page buffer 12 outputs data with a certain data size, e.g., data in a unit of 16 bits, to the data bus IOBUS via the pipe circuit (the buffer circuit) 125 supporting the 16 bits. When the flash memory 1 is driven in the ECC mode, the page buffer 12 outputs data in a unit of 32 bits to the data bus IOBUS via multiple pipe units 125.

Accordingly, the flash memory according to the embodiment can prevent the internal configuration of the flash memory and the control of the operation from becoming complex.

When a global I/O line method using complementary I/O lines (data lines) is used, the two I/O lines having the complementary relationship are connected with each sense/latch unit and the sense amplifier/data latch thereinside.

When the global I/O line method is used, there is a case where a current mirror-type differential sense amplifier is connected between the complementary global I/O line and the data bus (the data transfer circuit). Furthermore, there is a case where a timer, a latch, and a tri-state buffer are connected with the current mirror-type differential sense amplifier to control the operation and adjust the timing.

Furthermore, when the pipe line processing is used for the data transfer, the multiple buffer circuits is connected with the global I/O line. To adjust timing of the pipe line processing, a delay circuit is connected with each buffer circuit.

The global I/O line has a relatively long wire length and has a relatively large number of circuits and devices to be connected with the complementary global I/O line. Thus, a load generated in the I/O (e.g., a parasitic capacitance and a parasitic resistance) tends to be large.

To alleviate a delay of the operation due to the load caused in the I/O line, a memory may be driven at a data transfer rate meeting a predetermined specification by executing an interleave operation or simultaneous selection operation (parallel operation). To execute the interleave operation or the simultaneous selection operation, a wire, a circuit, and a control signal are added to the memory. As a result, the area occupied by the wire and the circuit for the interleave operation and the simultaneous selection operation tends to increase and the control of operating the flash memory tends to be complex.

On the other hand, in the flash memory 1 according to the embodiment, the wired OR I/O line method is used in the data buses IOBUS, XBUS which connect between the page buffer 12 and the data transfer circuit 17.

When the wired OR I/O line method is used in the flash memory according to the embodiment, one local I/O line XBUS is connected with each sense/latch unit 30 in the page buffer 12. Then, one pipe unit (buffer) is connected between the one local I/O line XBUS and the data bus IOBUS (the data transfer circuit 17).

Like the present embodiment, the local I/O line method is used for the connection between the sense circuit 121 and pipe circuit 125 (the buffer unit) of the page buffer 12, and the wired OR I/O line method is used for the connection between the pipe circuit 125 and the data bus IOBUS, so that the number of the I/O lines (data lines) can be reduced. Accordingly, the flash memory according to the embodiment can reduce the number of devices and circuits which are connected with the I/O line can be reduced and the load caused in the I/O line can be reduced.

Consequently, the flash memory 1 according to the embodiment can shorten a period of charging and discharging the I/O line (a period in which a signal level transitions), the operation of the flash memory can be speeded up.

The flash memory 1 according to the embodiment does not need to execute an interleave operation and a simultaneous selection operation as the operation is speeded up. Therefore, a wire (an add line) and a circuit and a control signal (an Add signal) which are used for the interleave operation and the simultaneous operation can be reduced.

Accordingly, the flash memory according to the embodiment can reduce the number of circuits/devices which are connected with the I/O line, the number of signal lines, and the number of signals, so that areas of peripheral regions 81, 82 and an area and density of the RTL circuit region 82 can be prevented from increasing. Since the areas of the peripheral regions 81, 82 can be made smaller, the area of the memory cell array 10 can be made larger or a chip size can be made smaller.

As the number of the wires is recued and the number of the circuits/devices which are connected with the wire is reduced, the flash memory 1 according to the embodiment can suppress generation of a current, so that the power consumption of the flash memory can be reduced. Since the interleave operation and the simultaneous selection operation do not need to be executed, the flash memory 1 according to the embodiment can reduce the power consumption.

In the flash memory 1 according to the embodiment, the data transferred to the data bus IOBUS via the one-stage pipe circuit 125 (and the pipe unit PU) is transferred from the data transfer circuit 17 to an outside of the flash memory 1 by the FIFO method.

Like the flash memory 1 according to the embodiment, the data supplied via the one-stage pipe circuit 125 is received or transmitted with the FIFO method, so that the timing of the operation can be relatively easily designed. By using the FIFO method, the number of stages of the pipe circuit can be reduced. Accordingly, the flash memory 1 according to the embodiment can reduce an area occupied by the peripheral circuits on the chip. Like the embodiment, the pipe unit PU between the local I/O line XBUS are wired-OR connected to the data bus IOBUS. This can also contribute to reduce the area of the circuits.

The flash memory according to the embodiment can also reduce the power consumption with the data transfer using the buffering by the one-stage pipe circuit 125 and the FIFO method, as compared with the data transfer using a multi-stage buffer.

When the flow of the data (a direction of movement) and the flow of the clock are opposite to each other, the timing designing may be difficult. Also, in this case, a restriction is imposed on the layout of the ECC circuit in the chip. Thus, the ECC circuit may be laid out in a region near the data transfer path. When the ECC circuit is provided in a region near the data transfer path, the chip size may be prevented from being made smaller.

In the embodiment, the ECC circuit 20 is provided on the chip on which the memory cell array (a memory core unit) is provided. The control signal and the clock in the built-in ECC mode are independent from each other at the timing of data reading and the timing of data writing.

As a result, in the flash memory 1 according to the embodiment, the ECC circuit 20 is provided in a region far from the data transfer path on the chip and can be provided in a region in which an area density of the circuits is relatively low. Accordingly, the ECC circuit whose correction capability is high can be provided on the chip on which the memory cell array 10 is provided. Since the flash memory including the ECC circuit whose correction capability is relatively high (an area is larger) can be provided on the chip on which the memory cell array 10 is provided, a yield of the flash memory can be improved.

As for the layout of the ECC circuit 20 on the chip of the flash memory according to the embodiment, the ECC circuit is provided in a region far from the data transfer path. As a result, the flow of the data and the flow of the clock to be a reference for the operation can be in the same direction on the chip. Accordingly, in the embodiment, the timing can be easily designed between the circuits in the flash memory 1, and a flexibility of the layout of the ECC circuit 20 on the chip can be improved.

As described above, the flash memory according to the embodiment can execute the two operation modes of transferring data of different data sizes with a relatively simple circuit configuration by using the common circuits and data buses.

According to the embodiment, the characteristic/performance of the flash memory can be improved. Also, the embodiment can reduce the cost of producing the flash memory.

### (d) Applications

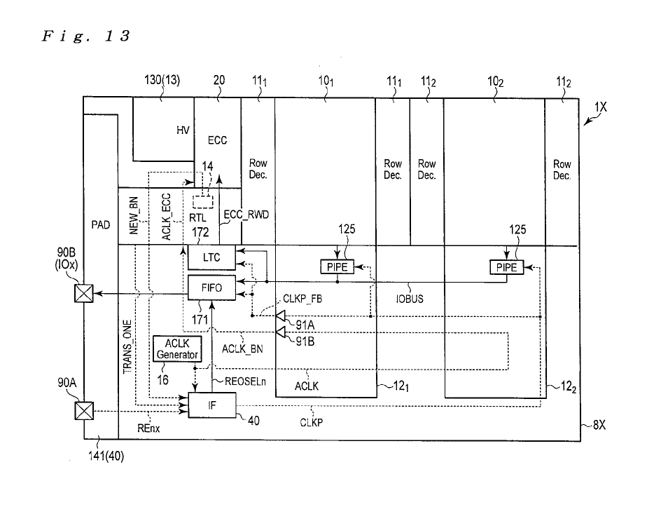

With reference to FIGS. 12 and 13, a semiconductor memory (e.g., a flash memory) according to the embodiment is described.

FIG. 12 is one example of a drawing showing one example of a chip layout of a flash memory showing an application of the flash memory according to the embodiment.

As shown in FIG. 12, when a storage capacity of a flash memory X1 is made larger, multiple memory cells 101, 102 are provided in one chip 8. Also, when the number of the memory cell arrays is not increased, a page size of the memory cell array, a block size, or the number of blocks is increased, so that the storage capacity of the flash memory 1X can be made larger.

For example, when one memory cell array has the storage capacity of 1 GB (gigabyte), as shown in FIG. 12, the two memory cell arrays 101, 102 are formed on one chip 8X, and thus the flash memory 1X with the storage capacity of 2 GB is provided.

When the multiple memory cell arrays 101, 102 are provided on one chip, the multiple the memory cell arrays 101, 102 are laid out on the chip 8X so as to adjacent to one other in a row direction.

Row decoders 111, 112 are respectively provided in the memory cell arrays 101, 102. In addition, page buffers 121, 122 are respectively provided in the memory cell arrays 101, 102.

In this manner, multiple memory cores (NAND cores) 101, 111, 121, 102, 112, 122 are provided in one chip 8X. The memory cores 101, 111, 121, 102, 112, 122 share each circuit such as a sequencer 14 or an ECC circuit 20.

The two NAND cores are provided between a side of the chip on which a pad region 141 is provided and a side facing to the pad region. The multiple memory cores 101, 111, 121, 102, 112, 122 are disposed adjacent to each other in the row direction on the chip 8X. The ECC circuit 20 is provided in a region between the memory cores 101, 111, 121 on the pad region 80 side and the pad region 80.

Even when one flash memory 1X has the multiple memory cores 101, 111, 121, 102, 112, 122, as similar to the layout example shown in FIG. 2, the ECC circuit 20 is provided in a region far from a data transfer path (in a region between the page buffers 121, 122 and the pad region 80), and is disposed between the row decoder 101 and the pad region 80. The ECC circuit 20 is laid out near a region whose area density on the chip 8X is low, e.g., in a high-voltage generation region 130.

FIG. 13 is one example of a drawing schematically showing flows of data and a control signal (clock) in the flash memory 1X including the multiple the memory cores. Note that in FIG. 13, the configuration which is common with the configuration shown in FIG. 9 is described as needed.

As shown in FIG. 13, the clock buses ACLK, CLKP are connected to the page buffer 121 on the pad region 80 side (the output side of the data) via the page buffer 122 positioned opposite to the pad region 80 among the two page buffers 121, 122 which respectively correspond to the two memory cell arrays 101, 102.

The data bus IOBUS is commonly used by the two page buffers 121, 122 and extends from the page buffer 122 to the data transfer circuit 17 via the page buffer 121.

In the flash memory 1X according to the application, the data transfer from each of the page buffers 121, 122 to the data transfer circuit 17 is executed via the one-stage buffer circuit and the data is transferred by the FIFO method. In the flash memory 1X according to the application, the ECC circuit 20 is provided in a position far from transmission paths of data and clocks. Then, in the flash memory 1X according to the application, the clock to be used for reading the data and the clock to be used for wiring the data are independent from each other.

Like the flash memory 1X according to the application, even when the multiple the memory cores 101, 111, 121, 102, 112, 122 are provided on one chip 8X, the flow of the data and the flow of the clock in data transfer have the same direction in which it flows from the page buffers 121, 122 to the data transfer circuit 17. Accordingly, both the data and internal clocks ACLK, CLKP flow from the page buffers 121, 122 to the data transfer circuit 17 in the data transfer (in reading the data).

Assumed here is a case where multiple memory cores (the memory cell arrays 101, 102) is provided on one chip in order to increase the storage capacity of the flash memory cell 1X. In this case, it is preferable that as shown in FIGS. 12, and 13, a circuit layout on the chip 8X including the multiple the memory cores be designed based on a circuit layout in which one memory core is provided in one chip as shown in FIG. 2.

When the storage capacity of the flash memory is increased, the wire length of the data bus and the wire length of the clock bus change correlatively. In other words, when a chip size is changed because the multiple the memory cell arrays (the memory cores) are mounted, the wire length of the clock bus is increased following the increase of the wire length of the data bus due to the change in the chip size.

For example, when the flow (a direction of movement) of the data is opposite to the flow of the clock bus on the chip, redesigning the timing between the circuits due to the increase of the wire length may become difficult.

As for the layout on the chip 8X in the flash memory 1X according to the application, the chip layout is designed so that the flow of the data and the flow of the clock to be a reference for the operation move in the same direction on the chip. In other words, the flash memory 1X is disposed so that the multiple the memory cores 102, 112, 122 are provided on a side opposite to the pad region of the flesh memory. As a result, the wire of the clock (the clock bus) simply needs to be extended to the side of the memory cores 102, 112, 122.

Accordingly, the flash memory according to the embodiment has little requirement of a complex redesign, such as the timing design between the buffer circuits, even when the storage capacity of the flash memory is increased and the chip size is changed as shown in FIGS. 12 and 13. Also, the flash memory according to the embodiment can improve the flexibility of the layout in the memory cell array and the peripheral circuits.

Thus, the flash memory according to the embodiment can obtain effects similar to those described in the embodiment and can provide an architecture which can improve an efficiency of designing the flash memory, as shown in the application of the flash memory according to the embodiment.

[Miscellaneous]

Although a flash memory is shown as an example as a semiconductor memory, the embodiment can be applied to memories such as MRAM (Magnetoresistive RAM), ReRAM (Resistive RAM), and PCRM (Phase Change RAM).

Although a several embodiments have been described, these embodiments are shown as an example, and do not intend to limit the scope of the invention. These inventive embodiments can be implemented by other various embodiments, and various omission, changes, modifications can be made without departing from the scope of the invention. These embodiments and modifications thereof are included in the scope of the invention and are included in the invention which is described in the scope of claims and a range of the equivalents thereof.

What is claimed is:

1. A semiconductor memory, comprising:
a first memory cell array including a plurality of memory cells configured to store data;
a first buffer circuit for inputting/outputting data to and from the first memory cell array;
a data transfer circuit connected with the first buffer circuit via a first data bus and configured to control data transfer based on a first mode for transferring data with a first bit width and a second mode for transferring data with a second bit width different from the first bit width; and
an ECC circuit connected with the first data bus via the data transfer circuit and configured to perform ECC processing on data with the second bit width, wherein
the first buffer circuit includes a plurality of pipe circuits each configured to input and output data with the first bit width, and
the data transfer circuit includes
a first data storage unit connected with the first data bus and having a plurality of first latch circuits configured to respectively stored a plurality of data with the first bit width transferred from the pipe circuits, and a selection circuit configured to connect one of the plurality of first latch circuits with a second data bus based on a selection signal, and
a second data storage unit connected between the first data bus and the ECC circuit and configured to store the data with the second bit width.

2. The semiconductor memory according to claim 1, wherein the data with the second bit width is formed of a plurality of data with the first bit width.

3. The semiconductor memory according to claim 1, wherein the second bit width is an integral multiple of the first bit width.

4. The semiconductor memory according to claim 1, wherein the data transfer circuit is configured to control data transfer between the first data bus and the second data bus based on a FIFO method.

5. The semiconductor memory according to claim 1, wherein the first buffer circuit is controlled based on a first internal clock, and the ECC circuit is controlled based on a second internal clock generated from an external clock or the first internal clock.

6. The semiconductor memory according to claim 3, wherein the data transfer circuit is controlled based on a second internal clock generated from a rebuffered external clock.

7. The semiconductor memory according to claim 1, wherein the first data bus has a width equal to the second bit width.

8. The semiconductor memory according to claim 7, wherein
in the first operation mode,
when first data is transferred to the first data bus, the data transfer circuit selects, as a selection data bus, a part of the first data bus having the first bit width, and
when second data following the first data is transferred to the first data bus, the data transfer circuit selects the other part of the first data bus having the first bit width and being different from the selection data bus.

9. The semiconductor memory according to claim 1, further comprising:
a first row control circuit provided adjacent to one end and the other end of the first memory cell array in a row direction and configured to control rows in the first memory cell array;
a second memory cell array including a plurality of memory cells configured to store data, and provided adjacent to the first memory cell array across the first row control circuit;
a second buffer circuit configured to input and output data to and from the second memory cell array;
a second row control circuit provided adjacent to one end and the other end of the second memory cell array in the row direction and configured to control rows of the second memory cell array; and
a pad region provided in an end portion of the chip on which the first and second memory cell arrays are provided,
wherein the ECC circuit is provided in a region between the first row control circuit and the pad region in the row direction.

10. The semiconductor memory according to claim 1, wherein
the first buffer circuit includes a sense latch unit having a plurality of sense circuits, and
each of the plurality of pipe circuits is connected with the sense latch unit via a third data bus.

11. A semiconductor memory, comprising:
a memory cell array including a plurality of memory cells storing data;
a first buffer circuit for inputting/outputting data to and from the first memory cell array;
a data transfer circuit connected with the first buffer circuit via the first data bus and configured to control data transfer; and
a control circuit configured to control a first mode and a second mode, wherein
the data transfer circuit performs control such that a bus width of the first data bus differs between the first mode and the second mode.

12. The semiconductor memory according to claim 11, further comprising an ECC circuit, wherein
the first mode is an operation mode without using the ECC circuit, and
the second mode is an operation mode using the ECC circuit.

13. The semiconductor memory according to claim 11, wherein
in the first more, the data transfer circuit divides the first data bus into a plurality of second data buses, and simultaneously transfers data to each of the second data buses,
in the second mode, the data transfer circuit simultaneously transfers data to the entire first data bus in the second mode.

14. The semiconductor memory according to claim 11, further comprising an ECC circuit, wherein
the first buffer circuit is controlled based on a first internal clock,
the ECC circuit is controlled based on a second internal clock generated from an external clock or the first internal clock, and
the data transfer circuit is controlled based on a second internal clock generated from the rebuffered external clock.

15. The semiconductor memory according to claim 11, wherein
the control circuit is configured to transfer data to the first buffer circuit and the data transfer circuit in this order and transfers an internal clock to the first buffer circuit and the data transfer circuit in this order.

16. The semiconductor memory according to claim 11, further comprising a latch circuit connected with the ECC circuit, wherein
the control circuit is configured to transfer data to the first buffer circuit, the data transfer circuit, and the latch circuit in this order and transfers an internal clock to the first buffer circuit, the data transfer circuit, and the latch circuit in this order.
